(19) United States
(12) Patent Application Publication
(10) Pub. No.: US 2007/0056628 A1
(43) Pub. Date: Mar. 15, 2007

(54) Photovoltaic cell comprising carbon nanotubes formed by electrophoretic deposition and method for fabricating the same

(76) Inventors: Young Jun Park, Suwon-Si (KR); Jung Gyu Nam, Yongin-Si (KR); Jin Young Kim, Suwon-Si (KR)

Correspondence Address: CANTOR COLBURN, LLP, 55 GRIFFIN ROAD SOUTH, BLOOMFIELD, CT, 06002, US

(21) Appl. No.: 11/393,310

(22) Filed: Mar. 30, 2006

(30) Foreign Application Priority Data
Sep. 12, 2005 (KR) 2005-84713

(51) Int. Cl. H01L 31/00

(52) U.S. Cl. 136/263

(57) ABSTRACT

A photovoltaic cell includes carbon nanotubes formed by electrophoretic deposition. A separate carbon nanotube layer is stacked on a semiconductor layer by electrophoretic deposition, or a mixed layer of carbon nanotubes and a constituent material of a semiconductor layer is formed by electrophoretic deposition, thereby preventing damage to the carbon nanotubes. A method for fabricating the photovoltaic cell is also provided. Since superior electrical conductivity of the carbon nanotubes is maintained unchanged, the photovoltaic cell exhibits improved electron transfer performance and inhibits accumulation of electrons and occurrence of recombination reactions.

This application claims priority to Korean Patent Application No. 2005-84713, filed on Sep. 12, 2005 and all the benefits accruing therefrom under 35 U.S.C. §119, and the contents of which in its entirety are herein incorporated by reference.

### BACKGROUND OF THE INVENTION

1. Field of the Invention

The present invention relates to a photovoltaic cell including carbon nanotubes (“CNTs”) formed by electrophoretic deposition and a method for fabricating the photovoltaic cell. More particularly, the present invention relates to a photovoltaic cell with improved electron transfer performance and high power conversion efficiency and including CNTs, and a method for fabricating the photovoltaic cell.

2. Description of the Related Art

In recent years, numerous studies have focused on various alternative energy sources for conventional fossil fuels to solve urgent energy consumption problems. Particularly, extensive research into effective utilization of natural energy resources, including wind power, atomic energy, and solar energy, has been conducted to replace petroleum resources that may be used up within the next several decades. Photovoltaic cells utilize inexhaustible solar energy, unlike other energy sources, and are environmentally friendly. Since the first selenium (Se) photovoltaic cell was developed in 1983, silicon (Si) photovoltaic cells have drawn a great deal of attention and interest.

However, since silicon photovoltaic cells incur considerable fabrication costs, there are some limitations in the practical application and improvement in the efficiency of the silicon photovoltaic cells. To overcome these limitations, the development of dye-sensitized photovoltaic cells that can be fabricated at reduced costs is actively under consideration.

Unlike silicon photovoltaic cells, dye-sensitized photovoltaic cells are photoelectrochemical photovoltaic cells that consist essentially of photosensitive dye molecules capable of absorbing visible rays to form electron-hole pairs and a transition metal oxide for transferring the generated electrons. Various dye-sensitized photovoltaic cells have hitherto been developed. Of these, a representative dye-sensitized photovoltaic cell was reported by Gratzel et al. in Switzerland in 1991. The photovoltaic cell developed by Gratzel et al. includes a semiconductor electrode composed of titanium dioxide nanoparticles covered with dye molecules, a counter electrode (a platinum electrode), and an electrolyte filled between the electrodes. Since this photovoltaic cell is fabricated at low costs per electric power generated when compared to conventional silicon cells, it has received a great deal of attention due to the possibility of replacement of conventional photovoltaic cells.

FIG. 1 shows the structure of a conventional dye-sensitized photovoltaic cell. Referring to FIG. 1, the dye-sensitized photovoltaic cell includes a semiconductor electrode 108 consisting of a transparent electrode 101 and a light-absorbing layer 104, an electrolyte 102, and a counter electrode 103. The light absorbing layer 104 is generally composed of a metal oxide 105 and a dye 107.

The dye 107 present in the light-absorbing layer 104 may show neutral state (S), a transition state (S*), and an ionic state (S⁺). When sunlight is incident on the dye, the dye molecules undergo electronic transitions from the ground state (S/S⁺) to the excited state (S*/S⁺) to form electron-hole pairs, and the excited electrons are injected into a conduction band (CB) of the metal oxide 105 to generate an electromotive force.

However, not all of the excited electrons are transferred to the conduction band of the metal oxide 105, since some electrons are bonded with the dye molecules to return to the ground state and some electrons transferred to the conduction band cause recombination reactions, e.g., participation in redox coupling inside the electrolyte, to lower the power conversion efficiency, which becomes a cause of reduction in electromotive power. Thus, inhibition of such recombination reactions is considered significant in improving the electrical conductivity of electrodes to increase the power conversion efficiency of photovoltaic cells.

In this connection, a photovoltaic cell has been proposed in which single-wall carbon nanotubes (“SWCNTs”) are mixed with TiO₂ to form a semiconductor layer for the purpose of improving the electrical conductivity of electrodes and increasing the power conversion efficiency (Song-Rim Jang, R. Vittal, and Kang-Jin Kim. 2004. Incorporation of Functionalized Single-Wall Carbon Nanotubes in Dye-Sensitized TiO₂ Solar Cells. Langmuir. 20. 9807-9810). However, since the semiconductor layer of the photovoltaic cell is formed by baking a mixture of carbon nanotubes and TiO₂ under a nitrogen atmosphere at above 280˜430° C. (see FIG. 2), at which collapse of the carbon nanotubes happens, or higher for a long time, the carbon nanotubes are severely damaged. This damage poses problems that the desired effects cannot be attained, uniform dispersion of the carbon nanotubes is difficult, and application to flexible substrates, e.g., plastic substrates, is impossible.

### BRIEF SUMMARY OF THE INVENTION

Therefore, the present invention solves the above problems of the prior art by providing a photovoltaic cell with improved electron transfer performance and increased power conversion efficiency wherein a separate carbon nanotube layer is stacked on a semiconductor layer so as to maintain the inherent characteristics of carbon nanotubes.

Exemplary embodiments of the present invention also provide a method for fabricating a photovoltaic cell with improved electron transfer performance and high power conversion efficiency by stacking a separate carbon nanotube layer on a semiconductor layer by electrophoretic deposition, or forming a mixed layer of carbon nanotubes and a constituent material of a semiconductor layer by electrophoretic deposition.

In accordance with exemplary embodiments of the present invention, a photovoltaic cell includes a transparent electrode, a semiconductor layer, a dye, a counter electrode, and an electrolyte wherein a carbon nanotube layer is formed on the semiconductor layer.

In accordance with other exemplary embodiments of the present invention, a method for fabricating a photovoltaic cell includes forming a semiconductor layer on one surface of a transparent electrode and forming a carbon nanotube layer on the semiconductor layer by electrophoretic deposition.

In accordance with still other exemplary embodiments of the present invention, a method for fabricating a photovoltaic cell includes forming a mixed layer of carbon nanotubes and a constituent material of a semiconductor layer on one surface of a transparent electrode by electrophoretic deposition.

### BRIEF DESCRIPTION OF THE DRAWINGS

The above and other features and advantages of the present invention will be more clearly understood from the following detailed description taken in conjunction with the accompanying drawings, in which:

FIG. 1 is a cross-sectional view schematically showing the structure of a conventional photovoltaic cell;

FIG. 2 is a graph showing the results of thermogravimetric analysis for carbon nanotubes under a nitrogen atmosphere;

FIG. 3 is a cross-sectional view schematically showing the structure of an exemplary embodiment of a photovoltaic cell according to the present invention;

FIG. 4a is a cross-sectional view showing the structure of an exemplary embodiment of a photovoltaic cell according to the present invention wherein the shape of an exemplary semiconductor layer is planar, and FIG. 4b is a cross-sectional view showing the structure of an exemplary embodiment of a photovoltaic cell according to the present invention wherein the shape of an exemplary semiconductor layer is irregular;

FIG. 5 is a cross-sectional view schematically showing the structure of another exemplary embodiment of a photovoltaic cell according to the present invention;

FIGS. 6a and 6b are diagrams showing the procedures of an exemplary method for fabricating an exemplary embodiment of a photovoltaic cell according to the present invention;

FIG. 7 shows diagrams showing the procedure of an exemplary method for fabricating another exemplary embodiment of a photovoltaic cell according to the present invention;

FIG. 8 is a scanning electron micrograph (“SEM”) showing the surface of a semiconductor layer on which a carbon nanotube layer is stacked in an exemplary embodiment of a photovoltaic cell fabricated in Example 1 of the present invention; and

FIG. 9 is a cross-sectional scanning electron micrograph (“SEM”) of an exemplary embodiment of a photovoltaic cell fabricated in Example 2 of the present invention.

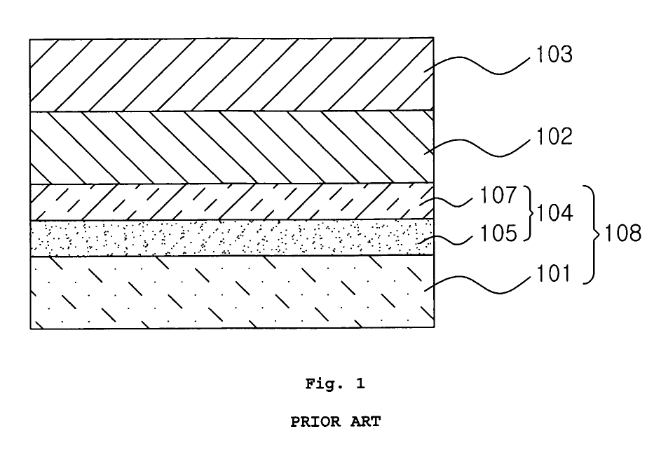

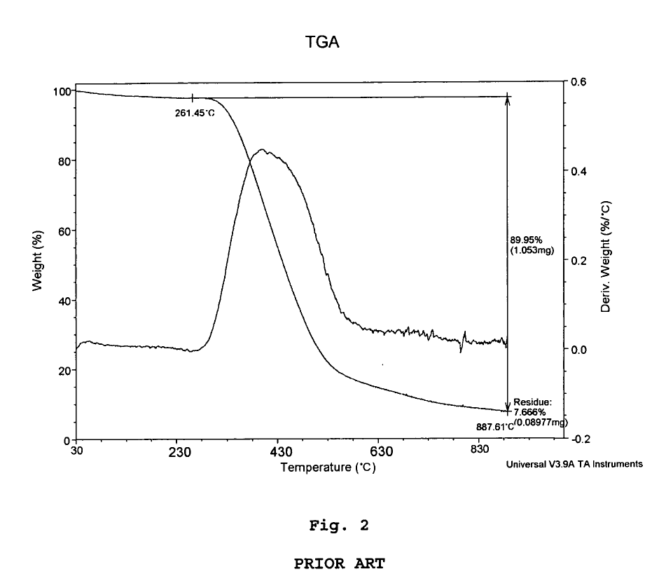

### DETAILED DESCRIPTION OF THE INVENTION

The invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout. Layers and elements are exaggerated for clarity.

As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, the present invention will be described in detail with reference to the accompanying drawings.

Exemplary embodiments of a photovoltaic cell of the present invention includes a carbon nanotube layer formed on a semiconductor layer by electrophoretic deposition so that superior electrical conductivity of carbon nanotubes is maintained to improve electron transfer performance of the photovoltaic cell, leading to high power conversion efficiency.

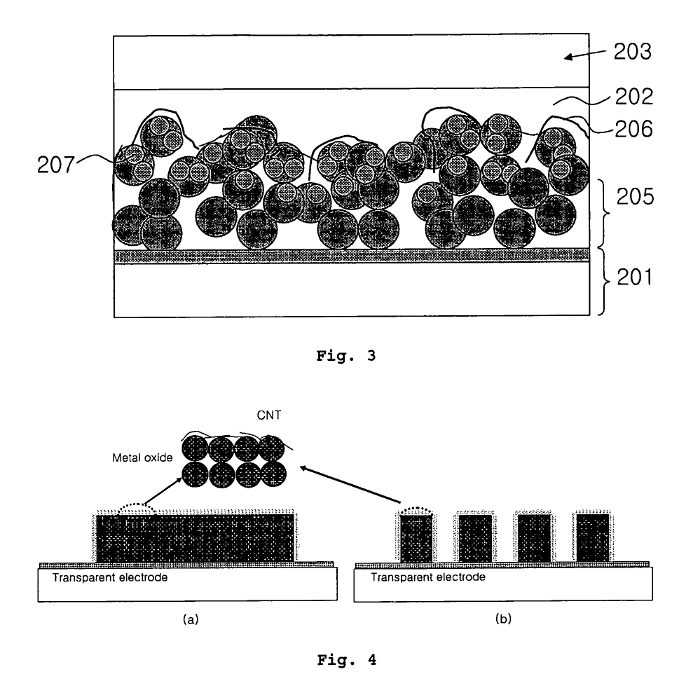

FIG. 3 is a cross-sectional view schematically showing the structure of an exemplary embodiment of a photovoltaic cell according to the present invention. Referring to FIG. 3, the photovoltaic cell of the present invention includes a transparent electrode 201 in which a conductive material is coated on a substrate, a semiconductor layer 205 formed on the transparent electrode 201, carbon nanotubes 206 stacked on the semiconductor layer 205, a dye 207 adsorbed on the surface of the semiconductor layer 205, a counter electrode 203 arranged opposite to the transparent electrode 201, and an electrolyte 202 filled into a space formed between the transparent electrode 201 and the counter electrode 203.

Since the photovoltaic cell of the present invention includes a separate carbon nanotube layer 206 formed on the semiconductor layer 205 to act as an electron transfer promoter, it allows electrons generated from the dye 207 to be easily transferred to a metal oxide semiconductor and facilitates mobility of the electrons within the semiconductor layer 205, and as a result, accumulation of the electrons and recombination reactions are inhibited, leading to an increase in power conversion efficiency.

The carbon nanotubes 206 included in the photovoltaic cell of the present invention are preferably formed on the semiconductor layer 205 by electrophoretic deposition. Since this separate stacking of the carbon nanotubes 206 on the semiconductor layer 205 avoids the need for baking at high temperatures, there is no danger of damage to the carbon nanotubes 206 and thus superior electrical conductivity of the carbon nanotubes 206 can be maintained.

Specifically, the carbon nanotubes 206 are directly attached to the porous metal oxide semiconductor layer 205 by electrophoretic deposition. At this time, the electrophoretic deposition is performed by applying a voltage of 0.001-0.02 V/μm for 10-180 seconds.

As the carbon nanotubes 306, there can be used single-wall carbon nanotubes, double-wall carbon nanotubes, multi-wall carbon nanotubes, or a mixture thereof.

The semiconductor layer 205 of the photovoltaic cell according to the present invention can be composed of a porous metal oxide. The metal oxide used herein is at least one compound selected from the group consisting of titanium oxide, niobium oxide, hafnium oxide, indium oxide, tin oxide, and zinc oxide and mixtures thereof. Theses metal oxides may be used alone or in combination as a mixture of two or more of the oxides. Titanium oxide (TiO₂) is preferably used.

The metal oxide constituting the semiconductor layer 205 preferably has a large surface area so that the dye 207 adsorbed on the surface of the metal oxide absorbs as much light as possible and the degree of adsorption to the electrolyte layer 202 is increased. It is preferred that the semiconductor layer 205 have nanostructures, such as nanotubes, nanowires, nanobelts or nanoparticles.

As shown in FIGS. 4a and 4b, the surface shape of the semiconductor layer 205 may be planar or irregular. When the semiconductor layer 205 has an irregular surface shape as shown in FIG. 4b, it can be sufficiently adsorbed to the dye 207, carbon nanotubes 206, and electrolyte 202 due to its increased surface area. Suitable irregular surface shapes of the semiconductor layer 205 are, but not limited to, step, needle, mesh, scar, and other shapes.

The semiconductor layer 205 may be formed into a monolayer or a bilayer structure using two or more kinds of metal oxides having different particle sizes. A preferred bilayer structure may include a 10-20 μm thick layer composed of a metal oxide having a particle size of 9-20 nm and a 3-5 μm thick layer composed of a metal oxide having a particle size of 200-400 nm. In such an example, the metal oxide layer with a larger particle size scatters light passed through the metal oxide layer with a smaller particle size and returns the scattered light toward the metal oxide layer with a smaller particle size, thus acting to improve the light transmittance.

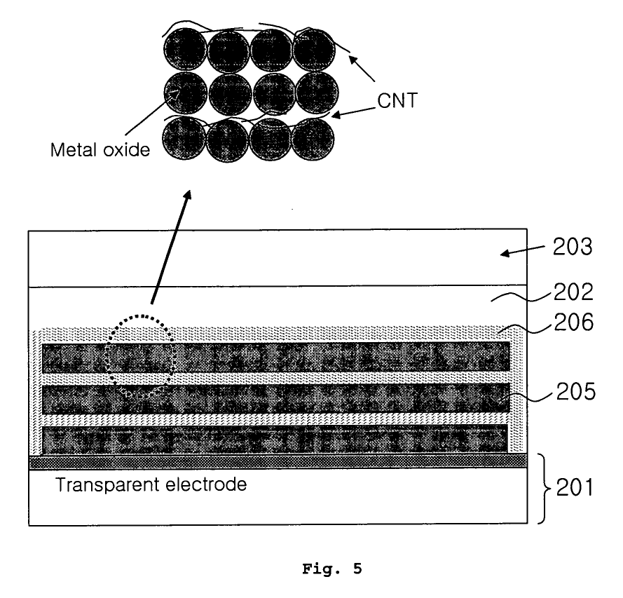

On the other hand, the photovoltaic cell of the present invention may be formed into a multilayer structure wherein the semiconductor layer 205 and the carbon nanotube layer 206 are alternately formed, as shown in FIG. 5. That is, a plurality of semiconductor layers 205 may be formed in the photovoltaic cell, separated from each other by a plurality of carbon nanotube layers 206. While three semiconductor layers 205 and three carbon nanotube layers 206 are illustrated, it should be understood that alternate numbers of semiconductor layers 205 and carbon nanotube layers 206 would be within the scope of these embodiments.

The transparent electrode 201 of the photovoltaic cell according to the present invention is formed by coating a substrate with a conductive material. The substrate may be of any type so long as it is transparent. Specifically, the substrate may be made of plastic or glass. Examples of conductive materials that can be coated on the substrate include, but are not limited to, indium tin oxide (“ITO”), fluorine-doped tin oxide (“FTO”), ZnO—Ga₂O₃, ZnO—Al₂O₃, and SnO₂—Sb₂O₃.

The photovoltaic cell of the present invention includes a dye 207 adsorbed on the surface of the semiconductor layer 205. The dye 207 absorbs light and undergoes electronic transitions from the ground state to the excited state to form electron-hole pairs. The excited electrons are injected into a conduction band (“CB”) of the metal oxide semiconductor layer 205 and transferred to the electrodes 201, 203 to generate an electromotive force.

The type of dye 207 employed in the photovoltaic cell is not particularly restricted so long as the dye 207 is generally used in the field of photovoltaic cells. Ruthenium complexes are preferred. In addition to ruthenium complexes, any colorant may be used without particular limitation if its charge separation functions and sensitizing functions are not impaired. As suitable colorants, there can be mentioned, for example: xanthene-type colorants, such as Rhodamine B, Rose Bengal, eosin and erythrosine; cyanine-type colorants, such as quinocyanine and cryptocyanine; basic dyes, phenosafranine, Capri blue, thiosine, and Methylene Blue; porphyrin-type compounds, such as chlorophyll, zinc porphyrin, and magnesium porphyrin; azo colorants; phthalocyanine compounds; complex compounds, such as Ru trisbipyridyl; anthraquinone-type colorants; polycyclic quinone-type colorants; and the like. These colorants may be used alone or in combination of two or more of the colorants. As the ruthenium complexes, there can be used RuL₂(SCN)₂, RuL₂ (H₂O)₂, RuL₃, and RuL₂ (wherein L is 2,2′-bipyridyl-4,4′-dicarboxylate).

The electrolyte 202 of the photovoltaic cell according to the present invention is composed of an electrolytic solution, for example, a solution of iodine in acetonitrile, an N-methyl-2-pyrrolidone (NMP) solution, or a 3-methoxypropionitrile solution. Any electrolytic solution may be used without limitation so long as it exhibits hole conductive functions.

The counter electrode 203 of the photovoltaic cell according to the present invention can be composed of, without limitation, electrically conductive materials. So long as a conductive layer is disposed on the surface of the counter electrode facing the transparent electrode 201, the counter electrode may also be composed of an insulating material. It is preferred that electrochemically stable materials be used as materials for the counter electrode 203. Specific examples of preferred materials for the counter electrode 203 include platinum, gold, and carbon.

For the purpose of improving catalytic effects of redox reactions, it is preferred that the surface of the counter electrode 203 facing the transparent electrode 201 has a fine structure with increased surface area. For example, the counter electrode 203 is preferably made of platinum or porous carbon. The platinum counter electrode 203 can be formed by physical vapor deposition like as sputtering, electron beam deposition. The porous carbon counter electrode 203 can be formed by sintering carbon particles or baking of an organic polymer.

An exemplary method for fabricating exemplary embodiments of the photovoltaic cell according to the present invention includes forming a semiconductor layer 205 on one surface of a transparent electrode 201 and forming a separate carbon nanotube layer 205 on the semiconductor layer 205 by electrophoretic deposition.

More specifically, the method of the present invention includes:

(a) forming a semiconductor layer 205 on one surface of a transparent electrode 201;

(b) forming a carbon nanotube layer 206 on the semiconductor layer 205 by electrophoretic deposition;

(c) adsorbing a dye 207 on the surface of the semiconductor layer 205; and

(d) arranging a counter electrode 203 so as to face the transparent conductive electrode 201 and filling an electrolyte 202 between the transparent conductive electrode 201 and the counter electrode 203.

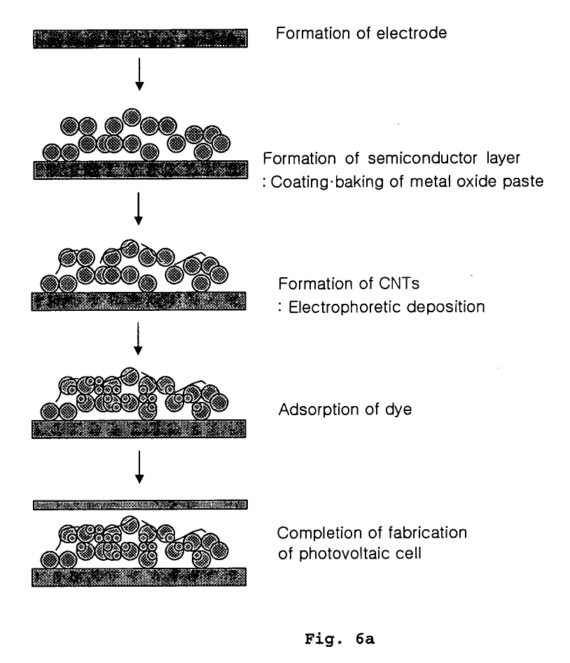

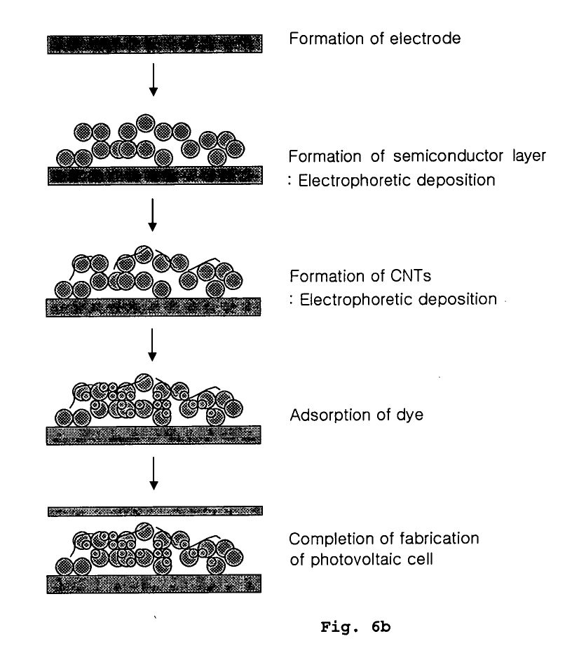

FIGS. 6a and 6b schematically show the procedures of exemplary methods according to the present invention. According to the exemplary methods of the present invention, since the layer of carbon nanotubes 206 having superior electrical conductivity are separately stacked on the semiconductor layer 205 by electrophoretic deposition, inherent characteristics of the carbon nanotubes 206 are advantageously maintained unchanged without undergoing need for baking.

Hereinafter, the exemplary method of the present invention will be further explained, based on the respective procedures.

(a):

First, a transparent electrode 201 coated with a conductive material is prepared. A metal oxide semiconductor layer 205 is formed on one surface of the transparent electrode 201.

The formation of the semiconductor layer 205 can be performed by a general coating technique, for example, spraying, spin coating, dipping, printing, doctor blading or sputtering, or electrophoretic deposition.

As is well known in the art, the formation of the semiconductor layer 205 by the general coating technique involves drying and baking after coating. The drying can be performed at about 50° C. to 150° C. The baking can be performed at about 400° C. to 500° C.

In contrast, the formation of the semiconductor layer 205 by electrophoretic deposition avoids the need for baking. At this time, the electrophoretic deposition is preferably performed by applying a voltage of 0.001-0.02 V/μm for 10-180 seconds.

For increased adsorption of the semiconductor layer 205 to the dye 207, carbon nanotubes 206 and electrolyte 202, the surface of the semiconductor layer 205 may formed into a planar or irregular shape in terms of increased surface area. The semiconductor layer 205 may have various irregular surface shapes, including but not limited to, step, needle, mesh, scar, and other shapes.

For improved transmittance, the semiconductor layer 205 may be formed into a monolayer or a bilayer structure using two or more kinds of metal oxides having different particle sizes. A preferred bilayer structure includes a 10-20 μm thick layer composed of a metal oxide having a particle size of 9-100 nm and a 3-5 μm thick layer composed of a metal oxide having a particle size of 200-400 nm.

(b):

In this procedure, carbon nanotubes 206 are stacked on the semiconductor layer 205 by electrophoretic deposition. Specifically, the electrophoretic deposition for forming a carbon nanotube layer 206 on the semiconductor layer 205 can be performed by applying a voltage of 0.001-0.02 V/μm for 10-180 seconds.

For better attachment of the carbon nanotubes 206 to the surface of the semiconductor layer 205 during electrophoretic deposition, the carbon nanotubes 206 are preferably treated with an acid and then dispersed in distilled water or a solvent to form an ionic state wherein the carbon nanotubes 206 are bonded to metal cations, which are positively-charged ions having fewer electrons than protons and are attracted to cathodes. The formation of the carbon nanotubes 206 into an ionic state can be performed by techniques commonly known in the art. For example, the carbon nanotubes 206 may be treated with an acid to cause the carbon nanotubes 206 to be negatively charged and then dispersed in MgO.H₂O for a given time to form an ionic bond (CNT⁻Mg⁺) with magnesium cations.

The exemplary method of the present invention may further include alternately repeating the procedures of (a) forming a semiconductor layer 205 and (b) forming a carbon nanotube layer 206 on the semiconductor layer 205 by electrophoretic deposition. The additional procedures are preferably carried out two to ten times. The final photovoltaic cell fabricated by this exemplary embodiment of the method has a multilayer structure wherein a plurality of semiconductor layers 205 and a plurality of carbon nanotube layers 206 are alternately formed, as previously described with reference to FIG. 5.

(c):

In this procedure, the semiconductor layer 205 on which the carbon nanotube layer 206 is stacked is impregnated with a solution containing a photosensitive dye 207 for 12 hours in accordance with techniques widely known in the art. Examples of suitable solvents that can be used in the solution containing a photosensitive dye 207 include tert-butyl alcohol, acetonitrile, and a mixture thereof.

(d):

In this procedure, first, the transparent conductive electrode 201 is adhered to a counter electrode 203 in a plane-to-plane manner using an adhesive, or other connecting elements, by techniques widely known in the art. After a fine hole (or holes) penetrating the counter electrode 203 is formed, an electrolytic solution is injected into a space formed between the transparent electrode 201 and the counter electrode 203 through the hole to form the layer of electrolytes 202. Thereafter, the hole is sealed using an adhesive, such as the adhesive used to adhere the counter electrode 203 to the transparent electrode 201. As the adhesive used herein, a thermoplastic polymer film (e.g., SURLYN, DuPont), an epoxy resin, ultraviolet (“UV”) hardener, or the like can be used. The adhesive, such as a thermoplastic polymer film, is interposed between the two electrodes 201 and 203, followed by thermal pressing, to adhere the electrodes 201 and 203 to each other.

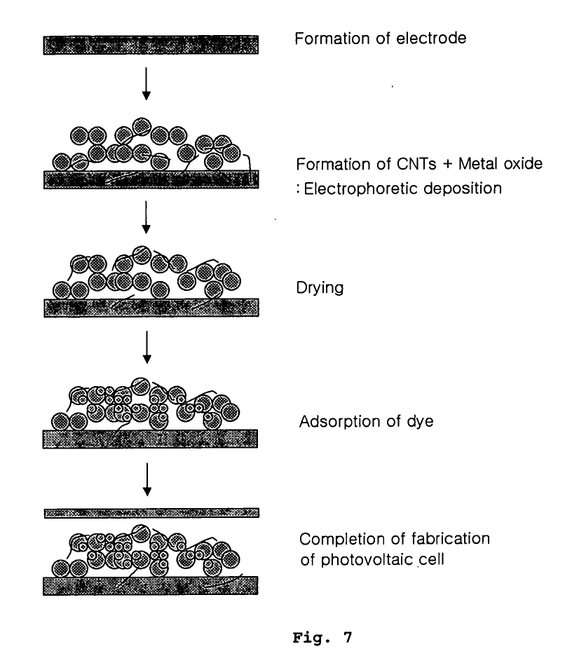

In addition to the exemplary method for fabricating the exemplary embodiments of a photovoltaic cell according to the present invention which includes forming a separate carbon nanotube layer 206 on a semiconductor layer 205 by electrophoretic deposition, the present invention also provides another exemplary method for fabricating exemplary embodiments of the photovoltaic cell including forming a mixed layer of carbon nanotubes and a constituent material of a semiconductor layer on a transparent electrode 201 by electrophoretic deposition, as demonstrated by FIG. 7.

That is, the exemplary method for fabricating the exemplary embodiment of the photovoltaic cell according to the present invention includes forming a mixed layer of carbon nanotubes 206 and a constituent material of a semiconductor layer 205 on one surface of a transparent electrode 201 by electrophoretic deposition.

More specifically, the exemplary method of the present invention includes:

(a) forming a mixed layer of carbon nanotubes 206 and a constituent material of a semiconductor layer 205 on one surface of a transparent electrode 201 by electrophoretic deposition;

(b) adsorbing a dye 207 on the surface of the constituent material; and

(c) arranging a counter electrode 203 so as to face the transparent conductive electrode 201 and filling an electrolyte 202 between the transparent conductive electrode 201 and the counter electrode 203.

As shown in FIG. 7, the exemplary method of the present invention includes forming a mixed layer of carbon nanotubes 206 and a constituent material of a semiconductor layer 205 on one surface of a transparent electrode 201 by electrophoretic deposition, unlike the previously described exemplary method of the present invention (see, FIGS. 6a and 6b). Since this method of the present invention does not involve baking, superior electrical conductivity characteristics of the carbon nanotubes 206 are maintained unchanged. Accordingly, the final photovoltaic cell fabricated by the exemplary method exhibits improved electron transfer performance and high power conversion efficiency.

In procedure (a), a mixed layer of carbon nanotubes 206 and a constituent material of a semiconductor layer 205 is formed on one surface of a transparent electrode 201 by electrophoretic deposition. At this time, the electrophoretic deposition is performed by applying a voltage of 0.001-0.02 V/μm for 10-180 seconds.

More specifically, a metal oxide constituting a semiconductor layer 205 and carbon nanotubes 206 in an ionic state are positioned together, and then a voltage of 0.001-0.02 V/μm is applied thereto for 10-180 seconds to form a mixed layer of the carbon nanotubes 206 and the constituent material of a semiconductor layer 205 on one surface of the transparent electrode 201. The formation of the carbon nanotubes 206 into an ionic state is performed by the same procedure as described above.

In this exemplary method of the present invention, procedures (b) and (c) other than step (a) (i.e. formation of a mixed layer of carbon nanotubes 206 and a constituent material of a semiconductor layer 205 on one surface of a transparent electrode 201 by electrophoretic deposition) can be carried out, without limitation, by techniques commonly known in the art, as previously described above.

On the other hand, details regarding the type and shapes of the transparent electrode 201, semiconductor layer 205, carbon nanotubes 206, dye 207, electrolyte 202 and counter electrode 201 that can be employed in the exemplary methods of the present invention are the same as described in the exemplary embodiments of the photovoltaic cell of the present invention.

The present invention will now be further described with reference to the following examples. It should be understood that these examples are given for the purpose of illustration only and are not to be construed as limiting the scope of the invention.

### EXAMPLE 1

Fluorine-doped tin oxide (“FTO”) was applied to a glass substrate using a sputter, and then a paste of TiO₂ particles having a particle diameter of 13 nm was applied thereto by screen printing. The resulting substrate was baked at 450° C. for 30 minutes to form a porous TiO₂ film having a thickness of about 15 μm. Separately, carbon nanotubes were treated with HCl, HNO₃, and the like, and dispersed in MgO.H₂O for 0.5 hours to form an ionic state. The carbon nanotubes in an ionic state were attached to the TiO₂ film by applying a voltage of 0.006 V/μm for 30 seconds in accordance with electrophoretic deposition. FIG. 8 is a scanning electron micrograph (“SEM”) showing the surface of the TiO₂ layer on which the carbon nanotubes are deposited. Referring to FIG. 8, the carbon nanotubes are formed on the surface of the TiO₂ layer. Subsequently, the resulting structure was dipped in a 0.3 mM ruthenium dithiocyanate 2,2′-bipyridyl-4,4′-dicarboxylate solution for 24 hours, and dried to adsorb the dye on the surface of the TiO₂ layer, fabricating a semiconductor electrode.

Then, a platinum film was deposited on a fluorine-doped tin oxide (“FTO”)-coated glass substrate using an electron beam evaporator, and a fine hole for injection of an electrolyte was formed thereon using a drill having a diameter of 1 mm to produce a counter electrode. Subsequently, a polymer (SURLYN, DuPont) having a thickness of about 40 μm was interposed between the counter electrode (anode) and the semiconductor electrode (cathode), and the two electrodes were adhered to each other under about 1 to about 3 atm. on a hot plate at about 100° C. to about 140° C. Next, an electrolytic solution was filled into a space formed between the two electrodes through the fine hole formed on the surface of the counter electrode to fabricate a photovoltaic cell of the present invention. At this time, as the electrolytic solution, an I₃⁻/I⁻ solution of 0.6 moles of 1,2-dimethyl-3-octyl-imidazolium iodide, 0.2 moles of LiIl, 0.04 moles of I₂ and 0.2 moles of 4-tert-butyl-pyridine (“TBP”) in acetonitrile was used.

### EXAMPLE 2

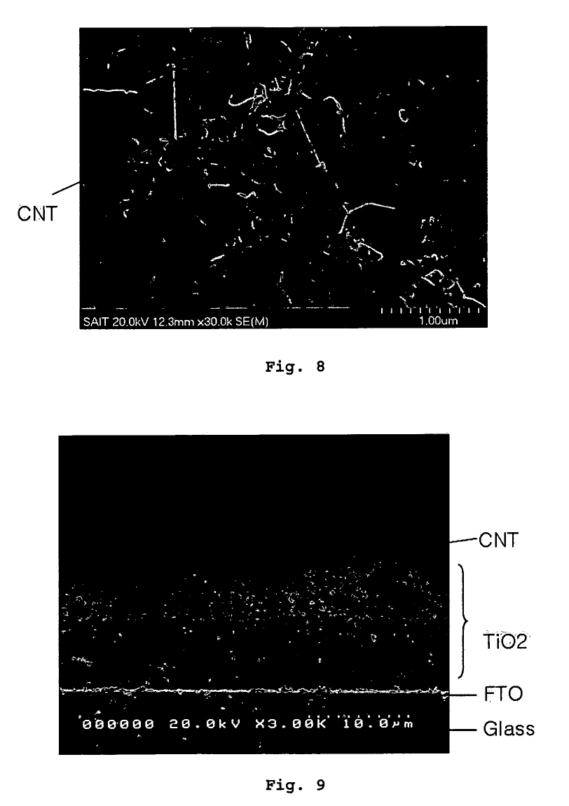

A photovoltaic cell was fabricated in substantially the same manner as in Example 1, except that a TiO₂ bilayer was formed by forming a 3 μm thick TiO₂ layer using a paste of TiO₂ particles having a diameter of 13 nm, and forming a 12 μm thick TiO₂ layer thereon using a paste of TiO₂ particles having a diameter of 300 nm. FIG. 9 is a cross-sectional scanning electron micrograph (“SEM”) of the photovoltaic cell.

### EXAMPLE 3

A photovoltaic cell was fabricated in substantially the same manner as in Example 1, except that the electrophoretic deposition was performed by applying a voltage of 0.006 V/μm for 60 seconds to form a carbon nanotube layer.

### EXAMPLE 4

A photovoltaic cell was fabricated in substantially the same manner as in Example 2, except that the electrophoretic deposition was performed by applying a voltage of 0.006 V/μm for 60 seconds to form a carbon nanotube layer.

### COMPARATIVE EXAMPLE 1

A photovoltaic cell was fabricated in substantially the same manner as in Example 1, except that no carbon nanotube layer was formed.

[Evaluation of Characteristics of Photovoltaic Cells]

To evaluate the power conversion efficiency of the devices fabricated in Examples 1 to 4 and Comparative Example 1, the photovoltages and photocurrents of the devices were measured.

For the measurements, a xenon lamp (Oriel, 01193) was used as a light source, and a standard photovoltaic cell (Frunhofer Institute Solar Engeriessysteme, Certificate No. C-ISE369, Type of material: Mono-Si⁺ KG filter) was used to compensate for the simulated illumination conditions (AM 1.5) of the xenon lamp. The current density (I_{sc}), voltage (V_{oc}) and fill factor (“FF”) of the devices were calculated from the obtained photocurrent-photovoltage curves, and the power conversion efficiency (ηₑ) of the devices was calculated according to the following equation:
ηₑ=(V_{oc}·I_{sc}·FF)/(P_{inc})

where P_{inc} is 100 mw/cm² (1 sun).

The obtained results are shown in Table 1.

TABLE 1

| | | | | Power conversion |
|---|---|---|---|---|
| Example No. | I_{sc} (mA/cm²) | V_{oc} (mV) | FF | efficiency (%) |
| Example 1 | 4.7 | 719.25 | 0.721 | 2.373 |
| Example 2 | 5.87 | 740.25 | 0.667 | 2.82 |
| Example 3 | 4.346 | 720.656 | 0.719 | 2.191 |
| Example 4 | 5.107 | 733.942 | 0.651 | 2.375 |
| Comparative | 4.034 | 684.446 | 0.617 | 1.563 |
| Example 1 | | | | |

As can be seen from the data shown in Table 1, the photovoltaic cells including carbon nanotubes formed by electrophoretic deposition according to the present invention exhibit much superior performance in all characteristics, including current density (I_{sc}), voltage (V_{oc}) and fill factor (FF) and power conversion efficiency, as compared to the photovoltaic cell fabricated in Comparative Example 1.

Thus, the present invention provides exemplary embodiments of a photovoltaic cell with improved electron transfer performance and high power conversion efficiency wherein a separate carbon nanotube layer is stacked on a semiconductor layer by electrophoretic deposition or a mixed layer of carbon nanotubes and a constituent material of a semiconductor layer is formed by electrophoretic deposition. The present invention also provides a method for fabricating the photovoltaic cell.

As apparent from the foregoing, since the photovoltaic cell of the present invention includes carbon nanotubes formed by electrophoretic deposition, superior electrical conductivity of carbon nanotubes is maintained, thus facilitating the mobility of electrons and inhibiting accumulation of electrons and occurrence of recombination reactions. Therefore, the exemplary embodiments of the photovoltaic cell of the present invention exhibits high power conversion efficiency.

Although the preferred embodiments of the present invention have been disclosed for illustrative purposes, those skilled in the art will appreciate that various modifications are possible, without departing from the scope and spirit of the invention as disclosed in the accompanying claims. It is to be understood that such modifications are within the scope of the present invention.

What is claimed is:

1. A photovoltaic cell comprising:
a transparent electrode including a conductive material coated on a substrate;
a semiconductor layer formed on the transparent electrode;
a carbon nanotube layer formed on the semiconductor layer;
a dye adsorbed on a surface of the semiconductor layer;
a counter electrode arranged opposite to the transparent electrode; and
an electrolyte filled within a space formed between the transparent electrode and the counter electrode.

2. The photovoltaic cell according to claim 1, wherein the carbon nanotube layer is formed by electrophoretic deposition.

3. The photovoltaic cell according to claim 2, wherein the electrophoretic deposition is performed by applying a voltage of 0.001-0.02 V/μm for 10-180 seconds.

4. The photovoltaic cell according to claim 1, wherein the semiconductor layer has a planar surface shape.

5. The photovoltaic cell according to claim 1, wherein the semiconductor layer has an irregular surface shape.

6. The photovoltaic cell according to claim 1, further comprising a plurality of semiconductor layers and a plurality of carbon nanotube layers, wherein the semiconductor layers and the carbon nanotube layers are alternately formed to form a multilayer structure.

7. The photovoltaic cell according to claim 1, wherein the conductive material is selected from a group consisting of indium tin oxide (ITO), fluorine-doped tin oxide (FTO), ZnO—Ga₂O₃, ZnO—Al₂O₃, and SnO₂—Sb₂O₃.

8. The photovoltaic cell according to claim 1, wherein the semiconductor layer includes a porous metal oxide, and the metal oxide is at least one compound selected from a group consisting of titanium oxide, niobium oxide, hafnium oxide, indium oxide, tin oxide, zinc oxide and mixtures thereof.

9. The photovoltaic cell according to claim 1, wherein carbon nanotubes in the carbon nanotube layer are selected from a group consisting of single-wall carbon nanotubes, double-wall carbon nanotubes, multi-wall carbon nanotubes, and mixtures thereof.

10. The photovoltaic cell according to claim 1, wherein the carbon nanotube layer is stacked on the semiconductor layer.

11. The photovoltaic cell according to claim 1, wherein the carbon nanotube layer is not baked.

12. A method for fabricating a photovoltaic cell comprising:
(a) forming a semiconductor layer on one surface of a transparent conductive electrode;
(b) forming a carbon nanotube layer on the semiconductor layer by electrophoretic deposition;
(c) adsorbing a dye on a surface of the semiconductor layer; and
(d) arranging a counter electrode so as to face the transparent conductive electrode and filling an electrolyte between the transparent conductive electrode and the counter electrode.

13. The method according to claim 12, wherein forming the semiconductor layer includes spraying, spin coating, dipping, printing, doctor blading, sputtering, or electrophoretic deposition.

14. The method according to claim 12, wherein forming a carbon nanotube layer on the semiconductor layer by electrophoretic deposition includes applying a voltage of 0.001-0.02 V/μm for 10-180 seconds.

15. The method according to claim 12, wherein forming the semiconductor layer includes applying a voltage of 0.001-0.02 V/μm for 10-180 seconds by electrophoretic deposition.

16. The method according to claim 12, wherein forming a semiconductor layer and forming a carbon nanotube layer on the semiconductor layer by electrophoretic deposition are alternately repeated to form a multilayer structure.

17. The method according to claim 12, further comprising forming the transparent conductive electrode by coating a conductive material on a plastic or glass substrate.

18. A method for fabricating a photovoltaic cell comprising:
(a) forming a mixed layer of carbon nanotubes and a constituent material of a semiconductor layer on one surface of a transparent conductive electrode by electrophoretic deposition;
(b) adsorbing a dye on a surface of the constituent material; and
(c) arranging a counter electrode so as to face the transparent conductive electrode and filling an electrolyte between the transparent conductive electrode and the counter electrode.

19. The method according to claim 18, wherein forming a mixed layer of carbon nanotubes and a constituent material of a semiconductor layer on one surface of a transparent conductive electrode by electrophoretic deposition includes applying a voltage of 0.001-0.02 V/μm for 10-180 seconds.

20. The method according to claim 18, further comprising forming the transparent conductive electrode by coating a conductive material on a plastic or glass substrate.

21. A method for fabricating a photovoltaic cell comprising:
forming carbon nanotubes within the photovoltaic cell by electrophoretic deposition.

22. The method according to claim 21, wherein electrical conductive properties of the carbon nanotubes are maintained by not baking the carbon nanotubes while fabricating the photovoltaic cell.

23. The method according to claim 21, wherein forming carbon nanotubes within the photovoltaic cell includes stacking a layer of the carbon nanotubes on a semiconductor layer by electrophoretic deposition.

24. The method according to claim 21, wherein forming carbon nanotubes within the photovoltaic cell includes mixing the carbon nanotubes with a constituent material of a semiconductor layer and forming the carbon nanotubes and the constituent material on an electrode by electrophoretic deposition.
